(19) United States
(12) Patent Application Publication
(10) Pub. No.: US 2014/0174791 A1
(43) Pub. Date: Jun. 26, 2014

(54) CIRCUIT BOARD AND MANUFACTURING METHOD THEREOF

(71) Applicant: UNIMICRON TECHNOLOGY CORP., Taoyuan (TW)

(72) Inventors: Cheng-Po Yu, Taoyuan County (TW); Han-Pei Huang, Taoyuan County (TW); Shang-Feng Huang, Taoyuan County (TW)

(73) Assignee: UNIMICRON TECHNOLOGY CORP., Taoyuan (TW)

(21) Appl. No.: 13/726,659

(22) Filed: Dec. 26, 2012

(51) Int. Cl. H05K 3/06; H05K 1/02

(52) U.S. Cl. CPC H05K 3/067; H05K 1/0298
USPC 174/251; 427/97.2

(57) ABSTRACT

A circuit board and a manufacturing method thereof are provided. A dielectric layer is formed on a substrate, wherein an internal circuit layer is formed on the substrate and the dielectric layer covers the internal circuit layer. A first trench, a second trench and an opening are formed in the dielectric layer. The opening is located below the first trench and connected with the first trench, and a portion of the internal circuit layer is exposed by the opening. A patterned conductive layer is formed on the dielectric layer. The patterned conductive layer covers a portion of the dielectric layer and fills the first trench, the second trench and the opening so as to form a first circuit layer, a second circuit layer and a conductive through via, respectively, wherein the conductive through via is electrically connected with the first circuit layer and the internal circuit layer.

### BACKGROUND OF THE INVENTION

1. Field of the Invention

The invention relates to a circuit board and a manufacturing method thereof, and in particular relates to a circuit board having both an embedded circuit layer and a surface circuit layer, and a manufacturing method thereof.

2. Description of Related Art

For the past few years, with rapid development of electronic technologies and high tech electronics industries being introduced, electronic products that are more humanized and with better functions have been continuously launched, and have been designed to be small, slim and lightweight. These electronic products are usually equipped with a circuit board with a conductive circuit.

In general, a subtractive process can be used to manufacture a circuit layer in a circuit board when manufacturing the circuit board. However, during the subtractive process, if a conductive layer for forming the circuit layer is too thick, which will lead to a long time to etch, and an etching solution will accumulate to form a pond between circuit patterns and influence etching capability. In addition, during the etching process, if the conductive layer is too thick, usually a longer etching time is needed, which consequently makes the etching solution cause a serious lateral etching effect on the side walls of a circuit pattern, affecting the quality and reliability of a circuit, and also is disadvantageous for manufacture of a fine circuit. On the other hand, if the thickness of the conductive layer is decreased for avoiding the above problems, the thermal capacity of a formed structure will be consequently inadequate and thus a good heat dissipating capability cannot be provided.

Besides, in terms of the current process of manufacturing an embedded circuit, after forming a conductive layer on a dielectric layer and in a trench in the dielectric layer by electroplating, etching needs to be performed to remove an unnecessary portion of the conductive layer to form an embedded circuit. However, after etching is performed, usually the surface of the dielectric layer in the trench is easily exposed, which consequently affects follow-up processes.

Additionally, when a semi-additive process (SAP) is used for manufacturing a fine circuit, the contact area between a circuit and a dielectric layer is often too small, which results in the fine circuit having inadequate peeling strength and easily being peeled from the dielectric layer, therefore decreasing the reliability of a circuit board.

Moreover, normally during a process of forming a conductive through via for connecting two circuit layers, an opening is usually formed in a dielectric layer and a conductive material layer is then filled in the opening. However, in the process of filling the opening with the conductive material layer, an aspect ratio of the opening is usually too big, which makes it uneasy to fill the conductive material in.

### SUMMARY OF THE INVENTION

The present invention provides a manufacturing method of a circuit board which is used to manufacture a circuit board having both an embedded circuit layer and a surface circuit layer.

The present invention also provides a circuit board which has both an embedded circuit layer and a surface circuit layer.

The present invention proposes a manufacturing method of a circuit board. The manufacturing method includes the following steps. Firstly, a dielectric layer is formed on a substrate, wherein the substrate has an internal circuit layer formed thereon, and the dielectric layer covers the internal circuit layer. Thereafter, a first trench, a second trench and an opening are formed in the dielectric layer, wherein the opening is located below the first trench and is connected with the first trench, and a portion of the internal circuit layer is exposed by the opening. Then, a patterned conductive layer is formed on the dielectric layer. The patterned conductive layer covers a portion of the dielectric layer and fills the first trench, the second trench and the opening so as to form a first circuit layer, a second circuit layer and a conductive through via, respectively, wherein the conductive through via is electrically connected with the first circuit layer and the internal circuit layer.

According to the manufacturing method of a circuit board as described in an embodiment of the present invention, the first circuit layer includes a first embedded circuit layer and a first surface circuit layer. The first embedded circuit layer is located in the first trench, and the first surface circuit layer is located on the dielectric layer and the first embedded circuit layer. A boundary of the first embedded circuit layer is located within a boundary of the first surface circuit layer. The second circuit layer includes a second embedded circuit layer and a second surface circuit layer. The second embedded circuit layer is located in the second trench, and the second surface circuit layer is located on the dielectric layer and the second embedded circuit layer. A boundary of the second embedded circuit layer is located within a boundary of the second surface circuit layer.

According to the manufacturing method of a circuit board as described in an embodiment of the present invention, an activation layer is formed on the dielectric layer and the portion of the internal circuit layer exposed by the opening after the first trench, the second trench and the opening are formed and before the patterned conductive layer is formed.

According to the manufacturing method of a circuit board as described in an embodiment of the present invention, a forming method of the patterned conductive layer includes the following steps. Firstly, a bottom conductive layer is formed on the activation layer. Then, a conductive material layer is formed on the bottom conductive layer, wherein the conductive material layer fills the first trench, the second trench and the opening. Then, a patterned photoresist layer is formed. The patterned photoresist layer covers the conductive material layer located above the first trench and the second trench and around the first trench and the second trench. Thereafter, the patterned photoresist layer is used as a mask; a portion of the conductive material layer and a portion of the bottom conductive layer are removed. Then, the patterned photoresist layer is removed.

According to the manufacturing method of a circuit board as described in an embodiment of the present invention, a forming method of the patterned conductive layer includes the following steps. Firstly, a bottom conductive layer is formed on the activation layer. Then, a patterned photoresist layer is formed on the bottom conductive layer, wherein the patterned photoresist layer exposes the first trench, the second trench and the bottom conductive layer around the first trench and the second trench. Following that, a conductive material layer is formed on the bottom conductive layer exposed by the patterned photoresist layer, wherein the conductive material fills the first trench, the second trench and the opening. Thereafter, the patterned photoresist layer and the bottom conductive layer located below the patterned photoresist layer are removed.

According to the manufacturing method of a circuit board as described in an embodiment of the present invention, the dielectric layer contains a plurality of activation particles and a portion of the activation particles are exposed when the first trench, the second trench and the opening are formed.

According to the manufacturing method of a circuit board as described in an embodiment of the present invention, a forming method of the patterned conductive layer includes the following steps. Firstly, a bottom conductive layer is formed on the dielectric layer. Then, a conductive material layer is formed on the bottom conductive layer and the portion of the internal circuit layer exposed by the opening, wherein the conductive material layer fills the first trench, the second trench and the opening. Following that, a patterned photoresist layer is formed. The photoresist layer covers the conductive material layer located on the first trench and the second trench and around the first trench and the second trench. Thereafter, the patterned photoresist layer is used as a mask; a portion of the conductive material layer and a portion of the bottom conductive layer are removed. Then, the patterned photoresist layer is removed.

According to the manufacturing method of a circuit board as described in an embodiment of the present invention, a forming method of the patterned conductive layer includes the following steps. Firstly, a bottom conductive layer is formed on the dielectric layer. Next, a patterned photoresist layer is formed on the bottom conductive layer. The patterned photoresist layer exposes the first trench, the second trench and the bottom conductive layer around the first trench and the second trench. Then, a conductive material layer is formed on the bottom conductive layer and a portion of the internal circuit layer exposed by the patterned photoresist layer, wherein the conductive material layer fills the first trench, the second trench and the opening. Thereafter, the patterned photoresist layer and the bottom conductive layer located below the patterned photoresist layer are removed.

The present invention also provides a circuit board including a substrate, an internal circuit layer, a dielectric layer, a first circuit layer, a second circuit layer, and a conductive through via. The internal circuit layer is disposed on the substrate. The dielectric layer is disposed on the substrate and covers the internal circuit layer. The first circuit layer includes a first embedded circuit layer and a first surface circuit layer. The first embedded circuit layer is embedded in the dielectric layer. The first surface circuit layer is disposed on the dielectric layer and the first embedded circuit layer. A second circuit layer includes a second embedded circuit layer and a second surface circuit layer. The second embedded circuit layer is embedded in the dielectric layer. The second surface circuit layer is disposed on the dielectric layer and the second embedded circuit layer. The conductive through via is disposed in the dielectric layer and is electrically connected with the first embedded circuit layer and the internal circuit layer.

According to the circuit board as described in an embodiment of the present invention, a boundary of the first embedded circuit layer is located within a boundary of the first surface circuit layer, and a boundary of the second embedded circuit layer is located within a boundary of the second surface circuit layer.

According to the circuit board as described in an embodiment of the present invention, an activation layer is further included. The activation layer is disposed between the dielectric layer and the first circuit layer, between the dielectric layer and the second circuit layer, between the dielectric layer and the conductive through via, and between the internal circuit layer and the conductive through via.

According to the circuit board as described in an embodiment of the present invention, a bottom conductive layer is further included. The conductive layer is disposed on the activation layer.

According to the circuit board as described in an embodiment of the present invention, the dielectric layer contains a plurality of activation particles.

According to the circuit board as described in an embodiment of the present invention, a bottom conductive layer is further included. The bottom conductive layer is disposed between the dielectric layer and the first circuit layer, between the dielectric layer and the second circuit layer, and between the dielectric layer and the conductive through via.

Based on the aforementioned, in the present invention, the patterned conductive layer covers a portion of the dielectric layer and fills the first trench and the second trench so as to increase an overall thickness of the first circuit layer and the second circuit layer, to further increase a thermal capacity of each circuit layer to provide a good heat dissipating capability. In addition, since a contact area between the first as well as the second circuit layers and the dielectric layer is increased, an adhesion force of the circuit layers to the dielectric layer is increased so as to avoid decrease of reliability of the circuit board due to the circuit layers being peeled from the dielectric layer. Moreover, since the first trench is connected with the opening used for forming the conductive through via, an aspect ratio of the opening is decreased and it is also made easy to fill the opening with the conductive material layer in follow-up manufacturing processes, so as to form a conductive through via with good quality.

In order to make the aforementioned features and advantages of the present invention more comprehensible, embodiments accompanying figures are described in detail below.

### BRIEF DESCRIPTION OF THE DRAWINGS

FIGS. 1A-1E are cross-sectional schematic drawings showing a manufacturing method of a circuit board illustrated according to the first embodiment of the present invention.

FIGS. 2A-2D are cross-sectional schematic drawings showing a manufacturing method of a circuit board illustrated according to the second embodiment of the present invention.

FIGS. 3A-3B are cross-sectional schematic drawings showing a manufacturing method of a circuit board illustrated according to the third embodiment of the present invention.

FIGS. 4A-4B are cross-sectional schematic drawings showing a manufacturing method of a circuit board illustrated according to the fourth embodiment of the present invention.

### DESCRIPTION OF EMBODIMENTS

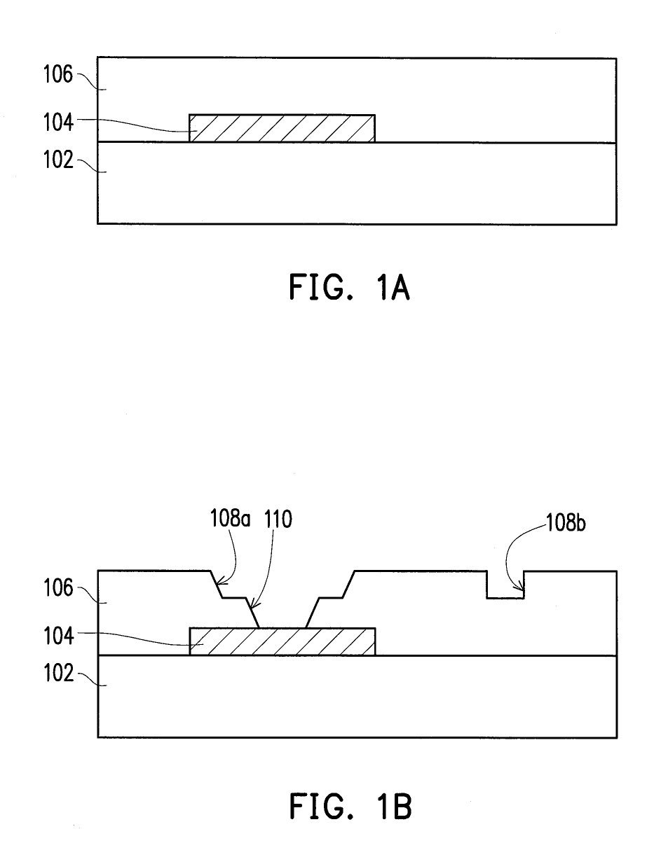

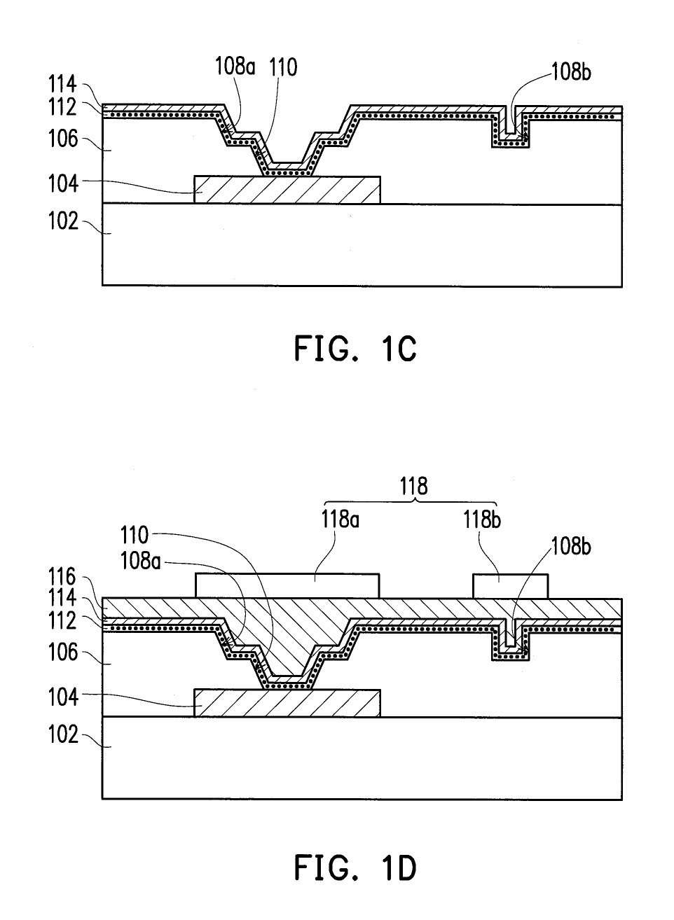

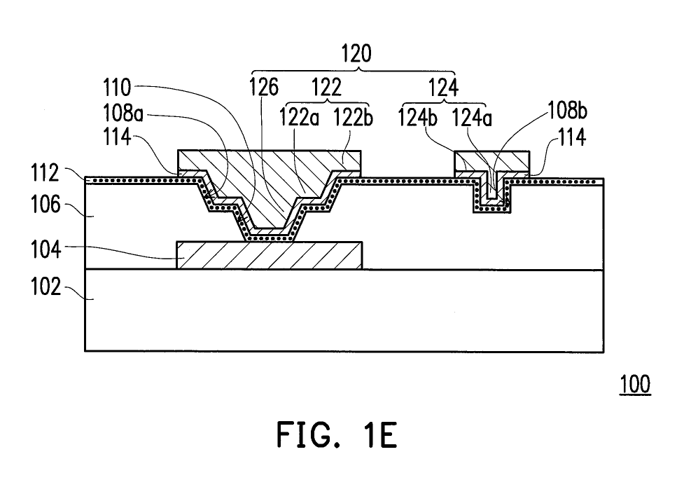

FIGS. 1A-1E are cross-sectional schematic drawings showing a manufacturing method of a circuit board illustrated according to the first embodiment of the present invention. Firstly, please refer to FIG. 1A, a dielectric layer 106 is formed on a substrate 102. The substrate 102 is, for example, a dielectric substrate. Besides, the substrate 102 has an internal circuit layer 104 formed thereon. The dielectric layer 106 covers the substrate 102 and the internal circuit layer 104. A material of the dielectric layer 106 is, for example, polypropylene (PP), polyimide (PI), Ajinomoto build-up film or liquid crystal polymer (LCP).

Then, please refer to FIG. 1B, a first trench 108a, a second trench 108b and an opening 110 are formed in the dielectric layer 106, wherein the opening 110 is located below the first trench 108a and connected with the first trench 108a. Besides, a portion of the internal circuit layer 104 is exposed by the opening 110. The first trench 108a, the second trench 108b and the opening 110 are formed by, for example, laser drilling or mechanical drilling. Additionally, a forming method of the first trench 108a, the second trench 108b and the opening 110 is, for example, forming the first trench 108a and the second trench 108b in the dielectric layer 106, followed by forming the opening 110 in the dielectric layer 106 below the first trench 108a. However, the present invention is not limited to this. In other embodiments, the opening 110 can be formed in the dielectric layer 106 first, and then the first trench 108a and the second trench 108b can be formed.

In the present embodiment, the opening 110 is located below the first trench 108a and connected with the first trench 108a, which consequently leads to a decrease of an aspect ratio of the opening 110, and makes it easy to fill the opening 110 with conductive materials in follow-up manufacturing processes, so as to form a conductive structure with good quality.

Then, please refer to FIG. 1C, an activation layer 112 is formed on the dielectric layer 106 and on the portion of the internal circuit layer 104 exposed by the opening 110. In the present embodiment, the activation layer 112 is formed through, for example, chemical deposition. A material of the activation layer 112 is, for example, a transition metal complex. Following that, a bottom conductive layer 114 is formed through and on the activation layer 112. The bottom conductive layer 114 can be used as a seed layer in a follow-up electroplating process.

Then, please refer to FIG. 1D, a conductive material layer 116 is formed on the bottom conductive layer 114. The conductive material layer 116 fills the first trench 108a, the second trench 108b and the opening 110. The conductive material layer 116 is, for example, a cooper layer. The conductive material layer 116 is formed, for example, by carrying out an electroplating process with the bottom conductive layer 114 as a seed layer. A patterned photoresist layer 118 is then formed on the conductive material layer 116. In the present embodiment, the patterned photoresist layer 118 includes a first portion 118a and a second portion 118b, wherein the first portion 118a covers the conductive material layer 116 located above and around the first trench 108a; the second portion 118b covers the conductive material layer 116 located above and around the second trench 108b. Specifically, a boundary of the first trench 108a is located within a boundary of the first portion 118a, so as to avoid the first trench 108a from being exposed due to an over-removal of the conductive material layer 116 in a follow-up process wherein the patterned photoresist layer 118 is used as a mask for removing the conductive material layer 116. Similarly, a boundary of the second trench 108b is located within a boundary of the second portion 118b, so as to avoid the second trench 108b from being exposed due to an over-removal of the conductive material layer 116 in a follow-up process wherein the patterned photoresist layer 118 is used as a mask for removing the conductive material layer 116.

After that, please refer to FIG. 1E, a portion of the conductive material layer 116 and a portion of the bottom conductive layer 114 are removed using the patterned photoresist layer 118 as a mask, so as to form a first circuit layer 122, a second circuit layer 124 and a conductive through via 126, wherein the conductive through via 126 is connected with the first circuit layer 122 and the bottom conductive layer 114. Following that, the patterned photoresist layer 118 is removed to complete manufacture of a circuit board 100.

Specifically, the first circuit layer 122 includes a first embedded circuit layer 122a and a first surface circuit layer 122b. The first embedded circuit layer 122a is embedded in the dielectric layer 106. Besides, the first surface circuit layer 122b is disposed on the dielectric layer 106 and the first embedded circuit layer 122a, and a boundary of the first embedded circuit layer 122a is located within a boundary of the first surface circuit layer 122b. The second circuit layer 124 includes a second embedded circuit layer 124a and a second surface circuit layer 124b. The second embedded circuit layer 124a is embedded in the dielectric layer 106. Additionally, the second surface circuit layer 124b is disposed on the dielectric layer 106 and the second embedded circuit layer 124a, and a boundary of the second embedded circuit layer 124a is located within a boundary of the second surface circuit layer 124b.

In the present embodiment, the first circuit layer 122 is comprised of the first surface circuit layer 122b and the first embedded circuit layer 122a, hence having a bigger thickness and a higher thermal capacity for providing a good heat dissipating capability. Similarly, the second circuit layer 124 is comprised of the second surface circuit layer 124b and the second embedded circuit layer 124a, hence having a bigger thickness and a higher thermal capacity for providing a good heat dissipating capability.

Apart from that, since the bottom conductive layer 114 is formed on a top surface of the dielectric layer 106 and on surfaces of the trenches (the first trench 108a, the second trench 108b), an overlapping area between the circuit layers (the first circuit layer 122, the second circuit layer 124) and the dielectric layer 106 is increased, making the circuit layers uneasy to be peeled from the dielectric layer 106. As a result, a reliability of the circuit board 100 can be effectively enhanced.

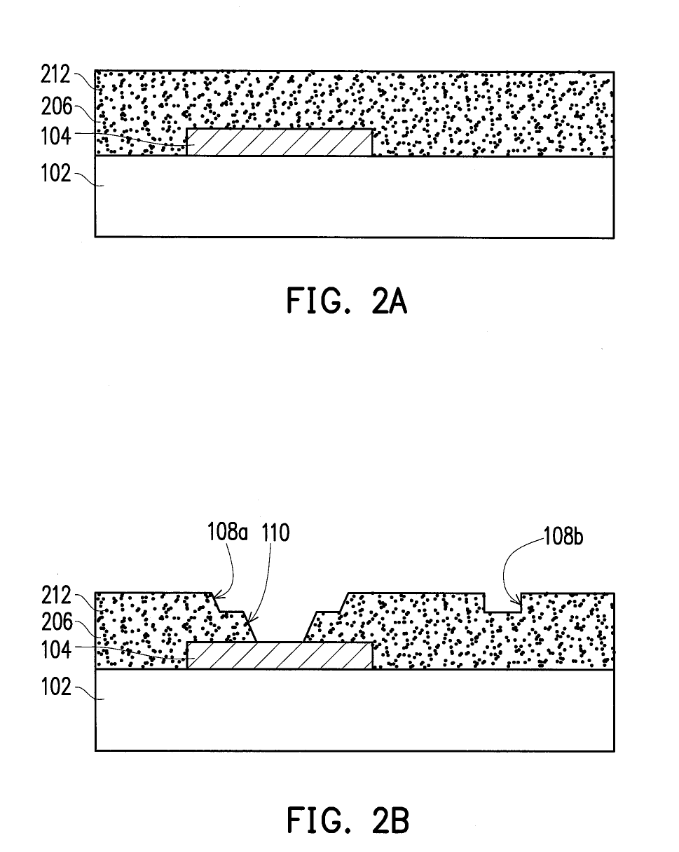

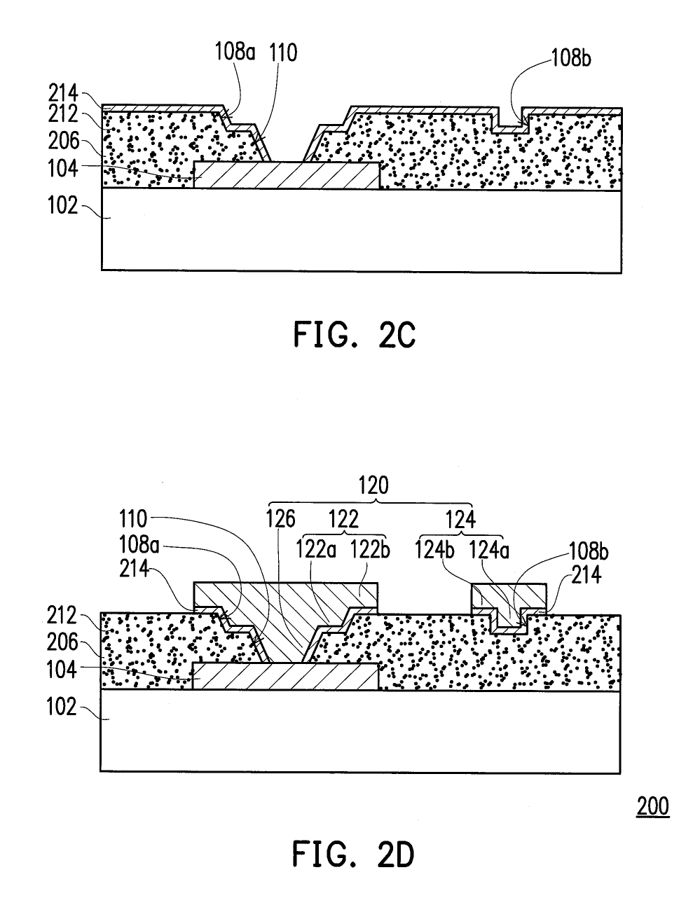

FIGS. 2A-2D are cross-sectional schematic drawings showing a manufacturing method of a circuit board illustrated according to the second embodiment of the present invention. The manufacturing method in the second embodiment is similar to the one in the first embodiment, and therefore, the same elements are labeled with the same numbers.

Firstly, please refer to FIG. 2A, a dielectric layer 206 is formed on the substrate 102, wherein the substrate 102 has the internal circuit layer 104 formed thereon. In the present embodiment, the dielectric layer 206 contains a plurality of activation particles 212, wherein the activation particles 212 are, for example, uniformly dispersed in the dielectric layer 206. A material of the activation particles 212 is, for example, a transition metal complex.

Then, please refer to FIG. 2B, the first trench 108a, the second trench 118b and the opening 100 are formed in the dielectric layer 206. In the present embodiment, a portion of the activation particles 212 in the dielectric layer 206 are exposed during forming of the first trench 108a, the second trench 118b and the opening 110.

Then, please refer to FIG. 2C, a bottom conductive layer 214 is formed on the dielectric layer 206 through the activation particles 212. The bottom conductive layer 214 can be used as a seed layer in a follow-up electroplating process. In the present embodiment, since the internal circuit layer 104 does not have the activation particles 212, the bottom conductive layer 214 is formed only on a surface of the dielectric layer 206 but not on the internal circuit layer 104.

Following that, the manufacturing processes as shown in FIGS. 1D and 1E are carried out to form a circuit board 200 as shown in FIG. 2D.

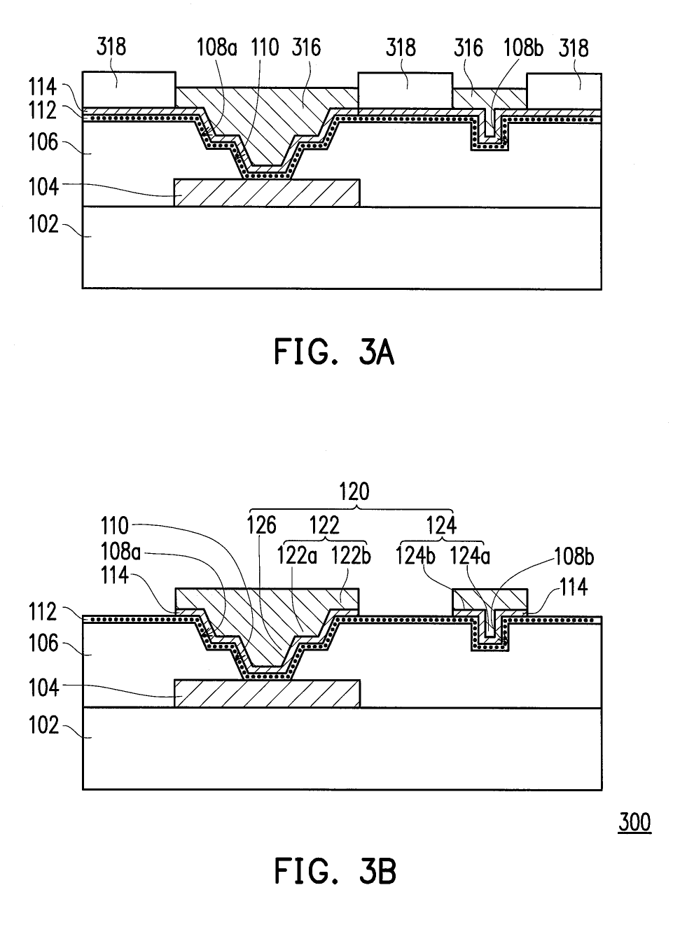

FIGS. 3A-3B are cross-sectional schematic drawings showing a manufacturing method of a circuit board illustrated according to the third embodiment of the present invention. The manufacturing method in the third embodiment is similar to the one in the first embodiment, and therefore, the same elements are labeled with the same numbers.

Firstly, the manufacturing processes as shown in FIGS. 1A-1C are carried out. Then, please refer to FIG. 3A, a patterned photoresist layer 318 is formed on the bottom conductive layer 114, wherein the patterned photoresist layer 318 exposes the first trench 108a, the second trench 108b and the bottom conductive layer 114 around the first trench 108a and the second trench 108b, i.e. the patterned photoresist layer 318 exposes areas where the circuit layers are to be formed.

Then, a conductive material layer 316 is formed on the bottom conductive layer 114 exposed by the patterned photoresist layer 318, wherein the conductive material layer 316 fills the first trench 108a, the second trench 108b and an opening 110, and the conductive material layer 316 covers the bottom conductive layer 114 around the first trench 108a and the second trench 108b.

Then, please refer to FIG. 3B, the patterned photoresist layer 318 and the bottom conductive layer 114 located below the patterned photoresist layer 318 are removed to form a patterned conductive layer 120 and to complete manufacture of a circuit board 300.

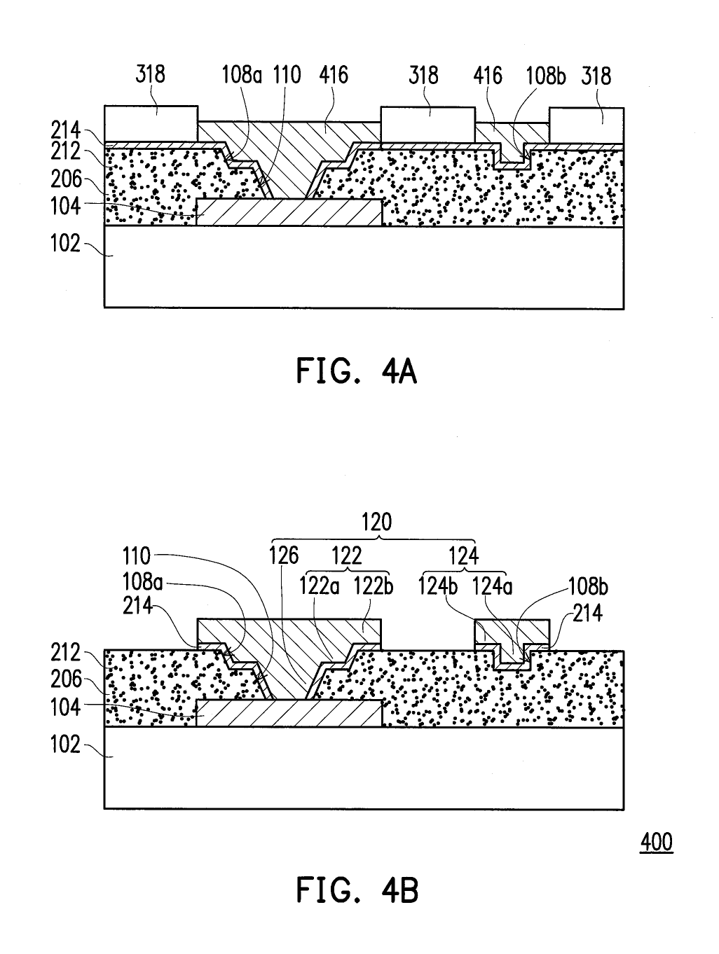

FIGS. 4A-4B are cross-sectional schematic drawings showing a manufacturing method of a circuit board illustrated according to the fourth embodiment of the present invention. The manufacturing method in the fourth embodiment is similar to the one in the second embodiment, and therefore, the same elements are labeled with the same numbers.

Firstly, the manufacturing processes as shown in FIGS. 2A-2C are carried out. Then, please refer to FIG. 4A, the patterned photoresist layer 318 is formed on the bottom conductive layer 214, wherein the patterned photoresist layer 318 exposes the first trench 108a, the second trench 108b and the bottom conductive layer 214 around the first trench 108a and the second trench 108b, i.e. the patterned photoresist layer 318 exposes areas where the circuit layers are to be formed.

Then, a conductive material layer 416 is formed on the bottom conductive layer 214 and a portion of the internal circuit layer 104 exposed by the patterned photoresist layer 318, wherein the conductive material layer 416 fills the first trench 108a, the second trench 108b and the opening 110, and the conductive material layer 416 covers the bottom conductive layer 114 around the first trench 108a and the second trench 108b.

Then, please refer to FIG. 4B, the patterned photoresist layer 318 and the bottom conductive layer 214 located below the patterned photoresist layer 318 are removed to form a patterned conductive layer 120 and to complete manufacture of a circuit board 400.

In summary, the circuit layer in the present invention is comprised of an embedded circuit layer located in a dielectric layer and a surface circuit layer located on a surface of the dielectric layer, hence having a bigger thickness for increasing thermal capacity to further provide a good heat dissipating capability.

In addition, in the present invention, since an overlapping area between a circuit layer and a dielectric layer is increased, decrease of reliability of the circuit board due to the circuit layer being peeled from the dielectric layer can be avoided.

Moreover, since a trench for forming the embedded circuit layer is connected with an opening for forming a conductive through via, an aspect ratio of the opening is decreased, and it is also made easy to fill the opening with conductive materials in follow-up manufacturing processes, so as to form a conductive through via with good quality.

Although the present invention has been disclosed with the above embodiments, they are not intended to limit the present invention. It will be apparent to one of ordinary skill in the art that modifications and variations to the described embodiments may be made without departing from the spirit and scope of the present invention. Therefore, the protection range of the present invention should be defined by the following claims.

What is claimed is:

1. A manufacturing method of a circuit board comprising:
forming a dielectric layer on a substrate, wherein the substrate has an internal circuit layer formed thereon, and the dielectric layer covers the internal circuit layer;
forming a first trench, a second trench, and an opening in the dielectric layer, wherein the opening is located below the first trench and is connected with the first trench, and the opening exposes a portion of the internal circuit layer;
forming a patterned conductive layer on the dielectric layer, the patterned conductive layer covering a portion of the dielectric layer and filling the first trench, the second trench and the opening, so as to form a first circuit layer, a second circuit layer and a conductive through via, wherein the conductive through via is electrically connected with the first circuit layer and the internal circuit layer.

2. The manufacturing method of a circuit board according to claim 1, wherein the first circuit layer comprises a first embedded circuit layer and a first surface circuit layer, the first embedded circuit layer being located in the first trench, the first surface circuit layer being located on the dielectric layer and the first embedded circuit layer, a boundary of the first embedded circuit layer being located within a boundary of the first surface circuit layer, and wherein the second circuit layer comprises a second embedded circuit layer and a second surface circuit layer, the second embedded circuit layer being located in the second trench, the second surface circuit layer being located on the dielectric layer and the second embedded circuit layer, a boundary of the second embedded circuit layer being located within a boundary of the second surface circuit layer.

3. The manufacturing method of a circuit board according to claim 2, wherein after forming the first trench, the second trench and the opening and before forming the patterned conductive layer, the method further comprises
forming an activation layer on the dielectric layer and on the portion of the internal circuit layer exposed by the opening.

4. The manufacturing method of a circuit board according to claim 3, wherein a forming method of the patterned conductive layer comprises:
forming a bottom conductive layer on the activation layer;
forming a conductive material layer on the bottom conductive layer, wherein the conductive material layer fills the first trench, the second trench and the opening;
forming a patterned photoresist layer, the patterned photoresist layer covering the conductive material layer located above the first trench and the second trench and around the first trench and the second trench;
removing a portion of the conductive material layer and a portion of the bottom conductive layer by using the patterned photoresist layer as a mask; and
removing the patterned photoresist layer.

5. The manufacturing method of a circuit board according to claim 3, wherein a forming method of the patterned conductive layer comprises:
forming a bottom conductive layer on the activation layer;
forming a patterned photoresist layer on the bottom conductive layer, the patterned photoresist layer exposing the first trench, the second trench and the bottom conductive layer around the first trench and the second trench;
forming a conductive material layer on the bottom conductive layer exposed by the patterned photoresist layer, wherein the conductive material layer fills the first trench, the second trench and the opening; and
removing the patterned photoresist layer and the bottom conductive layer located below the patterned photoresist layer.

6. The manufacturing method of a circuit board according to claim 1, wherein after forming the first trench, the second trench and the opening and before forming the patterned conductive layer, the method further comprises
forming an activation layer on the dielectric layer and on the portion of the internal circuit layer exposed by the opening.

7. The manufacturing method of a circuit board according to claim 6, wherein a forming method of the patterned conductive layer comprises:
forming a bottom conductive layer on the activation layer;
forming a conductive material layer on the bottom conductive layer, wherein the conductive material layer fills the first trench, the second trench and the opening;
forming a patterned photoresist layer, the patterned photoresist layer covering the conductive material layer located above the first trench and the second trench and around the first trench and the second trench;
removing a portion of the conductive material layer and a portion of the bottom conductive layer by using the patterned photoresist layer as a mask; and
removing the patterned photoresist layer.

8. The manufacturing method of a circuit board according to claim 6, wherein a forming method of the patterned conductive layer comprises:
forming a bottom conductive layer on the activation layer;
forming a patterned photoresist layer on the bottom conductive layer, the patterned photoresist layer exposing the first trench, the second trench and the bottom conductive layer around the first trench and the second trench;
forming a conductive material layer on the bottom conductive layer exposed by the patterned photoresist layer, wherein the conductive material layer fills the first trench, the second trench and the opening; and
removing the patterned photoresist layer and the bottom conductive layer located below the patterned photoresist layer.

9. The manufacturing method of a circuit board according to claim 1, wherein the dielectric layer contains a plurality of activation particles, and the plurality of activation particles are exposed while the first trench, the second trench and the opening are formed.

10. The manufacturing method of a circuit board according to claim 9, wherein a forming method of the patterned conductive layer comprises:
forming a bottom conductive layer on the dielectric layer;
forming a conductive material layer on the bottom conductive layer and on the portion of the internal circuit layer exposed by the opening, wherein the conductive material layer fills in the first trench, the second trench and the opening;
forming a patterned photoresist layer, the patterned photoresist layer covering the conductive material layer located above the first trench and the second trench and around the first trench and the second trench;
removing a portion of the conductive material layer and a portion of the bottom conductive layer using the patterned photoresist layer as a mask; and
removing the patterned photoresist layer.

11. The manufacturing method of a circuit board according to claim 9, wherein a forming method of a patterned conductive layer comprises:
forming a bottom conductive layer on the dielectric layer;
forming a patterned photoresist layer on the bottom conductive layer, the patterned photoresist layer exposing the first trench, the second trench and the bottom conductive layer around the first trench and the second trench;
forming a conductive material layer on the bottom conductive layer and the portion of the internal circuit layer exposed by the patterned photoresist layer, wherein the conductive material layer fills the first trench, the second trench and the opening; and
removing the patterned photoresist layer and the bottom conductive layer located below the patterned photoresist layer.

12. The manufacturing method of a circuit board according to claim 2, wherein the dielectric layer contains a plurality of activation particles, and the plurality of activation particles are exposed while the first trench, the second trench and the opening are formed.

13. The manufacturing method of a circuit board according to claim 12, wherein a forming method of the patterned conductive layer comprises:
forming a bottom conductive layer on the dielectric layer;
forming a conductive material layer on the bottom conductive layer and on the portion of the internal circuit layer exposed by the opening, wherein the conductive material layer fills in the first trench, the second trench and the opening;
forming a patterned photoresist layer, the patterned photoresist layer covering the conductive material layer located above the first trench and the second trench and around the first trench and the second trench;
removing a portion of the conductive material layer and a portion of the bottom conductive layer using the patterned photoresist layer as a mask; and
removing the patterned photoresist layer.

14. The manufacturing method of a circuit board according to claim 12, wherein a forming method of a patterned conductive layer comprises:
forming a bottom conductive layer on the dielectric layer;
forming a patterned photoresist layer on the bottom conductive layer, the patterned photoresist layer exposing the first trench, the second trench and the bottom conductive layer around the first trench and the second trench;
forming a conductive material layer on the bottom conductive layer and the portion of the internal circuit layer exposed by the patterned photoresist layer, wherein the conductive material layer fills the first trench, the second trench and the opening; and
removing the patterned photoresist layer and the bottom conductive layer located below the patterned photoresist layer.

15. A circuit board comprising:
a substrate;
an internal circuit layer disposed on the substrate;
a dielectric layer disposed on the substrate and covering the internal circuit layer;
a first circuit layer comprising a first embedded circuit layer and a first surface circuit layer, wherein the first embedded circuit layer is embedded in the dielectric layer, the first surface circuit layer being disposed on the dielectric layer and the first embedded circuit layer;
a second circuit layer comprising a second embedded circuit layer and a second surface circuit layer, wherein the second embedded circuit layer is embedded in the dielectric layer, the second surface circuit layer being disposed on the dielectric layer and the second embedded circuit layer; and
a conductive through via disposed in the dielectric layer, and electrically connected with the first embedded circuit layer and the internal circuit layer.

16. The circuit board according to claim 15, wherein a boundary of the first embedded circuit layer is located within a boundary of the first surface circuit layer, and a boundary of the second embedded circuit layer is located within a boundary of the second surface circuit layer.

17. The circuit board according to claim 16, further comprising an activation layer, disposed between the dielectric layer and the first circuit layer, between the dielectric layer and the second circuit layer, between the dielectric layer and the conductive through via, and between the internal circuit layer and the conductive through via.

18. The circuit board according to claim 17, further comprising a bottom conductive layer, disposed on the activation layer.

19. The circuit board according to claim 15, further comprising an activation layer, disposed between the dielectric layer and the first circuit layer, between the dielectric layer and the second circuit layer, between the dielectric layer and the conductive through via, and between the internal circuit layer and the conductive through via.

20. The circuit board according to claim 19, further comprising a bottom conductive layer, disposed on the activation layer.

21. The circuit board according to claim 15, wherein the dielectric layer contains a plurality of activation particles.

22. The circuit board according to claim 21, further comprising a bottom conductive layer, disposed between the dielectric layer and the first circuit layer, between the dielectric layer and the second circuit layer, and between the dielectric layer and the conductive through via.

23. The circuit board according to claim 16, wherein the dielectric layer contains a plurality of activation particles.

24. The circuit board according to claim 23, further comprising a bottom conductive layer, disposed between the dielectric layer and the first circuit layer, between the dielectric layer and the second circuit layer, and between the dielectric layer and the conductive through via.
